(19) United States
(12) Patent Application Publication
(10) Pub. No.: US 2026/0282863 A1
(43) Pub. Date: Sep. 17, 2026

(54) MANUFACTURING METHOD OF SEMICONDUCTOR STRUCTURE

(71) Applicant: Powerchip Semiconductor Manufacturing Corporation, Hsinchu (TW)

(72) Inventors: Pei-Rong Ni, Hsinchu (TW); Sheng Chieh Lin, Hsinchu City (TW); Chun-Lin Lu, Hsinchu City (TW)

(73) Assignee: Powerchip Semiconductor Manufacturing Corporation, Hsinchu (TW)

(21) Appl. No.: 19/176,130

(22) Filed: Apr. 10, 2025

(30) Foreign Application Priority Data
Mar. 12, 2025 (TW) 114109231

(51) Int. Cl. H10W 20/00; H10P 10/00

(52) U.S. Cl. CPC H10W 20/083; H10P 10/12

(57) ABSTRACT

A manufacturing method of a semiconductor structure including the following steps is provided. A wafer structure is provided. A first wafer is bonded to the wafer structure. The first wafer includes a first substrate and a first device layer located on the first substrate. After the first wafer is bonded to the wafer structure, a first opening is formed in the first substrate. The first opening exposes the first device layer. A dielectric layer is formed on the first substrate and in the first opening. A first through-substrate via (TSV) passing through the first opening is formed in the dielectric layer. The first TSV extends into the first device layer.

### CROSS-REFERENCE TO RELATED APPLICATION

This application claims the priority benefit of Taiwan application serial no. 114109231, filed on Mar. 12, 2025. The entirety of the above-mentioned patent application is hereby incorporated by reference herein and made a part of this specification.

### BACKGROUND

### Technical Field

The invention relates to a manufacturing method of a semiconductor structure, and particularly relates to a manufacturing method of a semiconductor structure having a through-substrate via (TSV).

### Description of Related Art

Some semiconductor structures have the TSV passing through the substrate. The TSV may be used to electrically connect stacked integrated circuits together. However, the current TSV process has the adverse effect on the semiconductor device in the device layer.

### SUMMARY

The invention provides a manufacturing method of a semiconductor structure, which can prevent the TSV process from causing the adverse effect on the semiconductor device in the device layer.

The invention provides a manufacturing method of a semiconductor structure, which includes the following steps. A wafer structure is provided. A first wafer is bonded to the wafer structure. The first wafer includes a first substrate and a first device layer located on the first substrate. After the first wafer is bonded to the wafer structure, a first opening is formed in the first substrate. The first opening exposes the first device layer. A dielectric layer is formed on the first substrate and in the first opening. A first through-substrate via (TSV) passing through the first opening is formed in the dielectric layer. The first TSV extends into the first device layer.

According to an embodiment of the invention, in the manufacturing method of the semiconductor structure, the minimum width of the first opening may be greater than the maximum width of the first TSV.

According to an embodiment of the invention, in the manufacturing method of the semiconductor structure, the first TSV may be in direct contact with the dielectric layer.

According to an embodiment of the invention, in the manufacturing method of the semiconductor structure, the first TSV may pass through the first device layer.

According to an embodiment of the invention, in the manufacturing method of the semiconductor structure, the first TSV may further extend into the wafer structure.

According to an embodiment of the invention, in the manufacturing method of the semiconductor structure, a width of a portion of the first opening closest to the first device layer may be smaller than a width of a portion of the first opening farthest from the first device layer.

According to an embodiment of the invention, in the manufacturing method of the semiconductor structure, the method of forming the first TSV may include the following steps. A second opening is formed in the dielectric layer and the first device layer. The first TSV is formed in the second opening.

According to an embodiment of the invention, in the manufacturing method of the semiconductor structure, the method of bonding the first wafer to the wafer structure may be a fusion bonding method.

According to an embodiment of the invention, in the manufacturing method of the semiconductor structure, the method of bonding the first wafer to the wafer structure may be a hybrid bonding method.

According to an embodiment of the invention, the manufacturing method of the semiconductor structure may further include the following step. Before the first opening is formed, a thinning process is performed on the first substrate.

According to an embodiment of the invention, in the manufacturing method of the semiconductor structure, the wafer structure may include a second wafer. The second wafer may include a second substrate and a second device layer located on the second substrate.

According to an embodiment of the invention, in the manufacturing method of the semiconductor structure, the second substrate does not have an opening aligned with the first opening.

According to an embodiment of the invention, in the manufacturing method of the semiconductor structure, the second substrate may have a second opening aligned with the first opening.

According to an embodiment of the invention, in the manufacturing method of the semiconductor structure, the wafer structure may include a blocking layer. The bottom portion of the first TSV may be in direct contact with the blocking layer.

According to an embodiment of the invention, the manufacturing method of the semiconductor structure may further include the following steps. A second opening is formed in the first substrate. The second opening may expose the first device layer. The dielectric layer is formed in the second opening. A second TSV passing through the second opening is formed in the dielectric layer. The second TSV extends into the first device layer.

According to an embodiment of the invention, in the manufacturing method of the semiconductor structure, the second TSV may be in direct contact with the dielectric layer.

According to an embodiment of the invention, in the manufacturing method of the semiconductor structure, the first TSV and the second TSV may have different depths in the wafer structure.

According to an embodiment of the invention, in the manufacturing method of the semiconductor structure, the wafer structure may include a second wafer. The second wafer may include a second substrate and a second device layer located on the second substrate.

According to an embodiment of the invention, in the manufacturing method of the semiconductor structure, the second substrate may have a third opening aligned with the first opening. The second substrate does not have an opening aligned with the second opening.

According to an embodiment of the invention, in the manufacturing method of the semiconductor structure, the second substrate may have a third opening aligned with the first opening. The second substrate may have a fourth opening aligned with the second opening.

Based on the above description, in the manufacturing method of the semiconductor structure according to the invention, after the first wafer is bonded to the wafer structure, the first opening is formed in the first substrate. The first opening exposes the first device layer. The dielectric layer is formed on the first substrate and in the first opening. The first TSV passing through the first opening is formed in the dielectric layer. Since the first opening, the dielectric layer, and the first TSV are formed after the first wafer is bonded to the wafer structure, the processes of the first opening, the dielectric layer, and the first TSV can be prevented from causing the adverse effect on the semiconductor device in the first device layer. In addition, since the processes of the first opening, the dielectric layer, and the first TSV are performed after the first wafer is bonded to the wafer structure, the degree of freedom in design can be increased.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A - 1F are cross-sectional views of a manufacturing process of a semiconductor structure according to some embodiments of the invention.

FIG. 2 is a cross-sectional view of a semiconductor structure according to other embodiments of the invention.

FIG. 3 is a cross-sectional view of a semiconductor structure according to other embodiments of the invention.

FIG. 4 is a cross-sectional view of a semiconductor structure according to other embodiments of the invention.

FIG. 5 is a cross-sectional view of a semiconductor structure according to other embodiments of the invention.

FIG. 6 is a cross-sectional view of a semiconductor structure according to other embodiments of the invention.

FIG. 7 is a top view of the semiconductor structure of FIG. 1F according to some embodiments of the invention.

FIG. 8 is a top view of the semiconductor structure of FIG. 1F according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. Furthermore, the features in the top view and the features in the cross-sectional view are not drawn to the same scale. In fact, the dimensions of the various features may be arbitrarily increased or reduced for clarity of discussion.

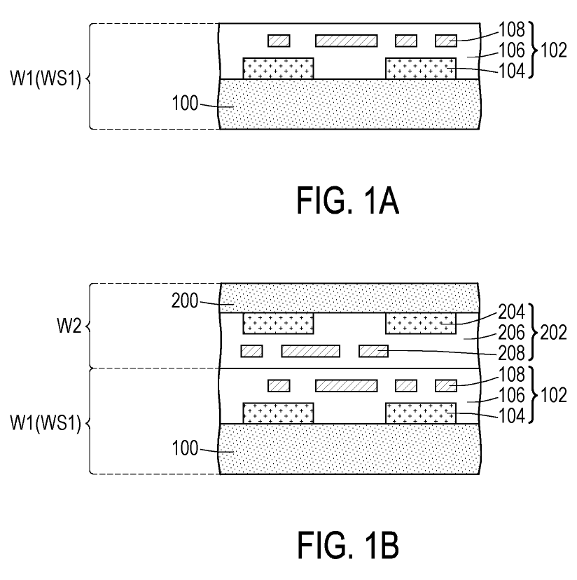

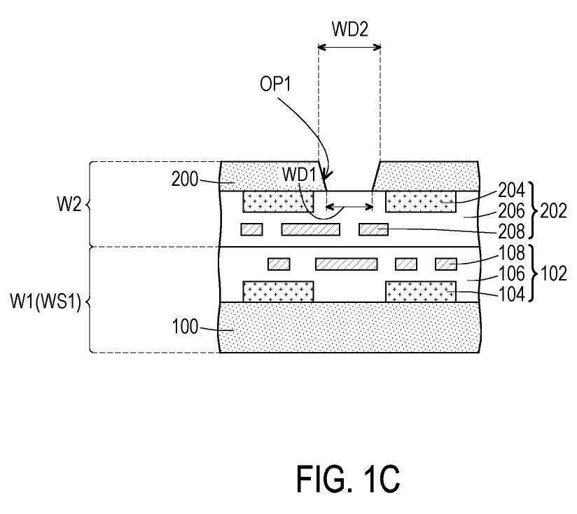

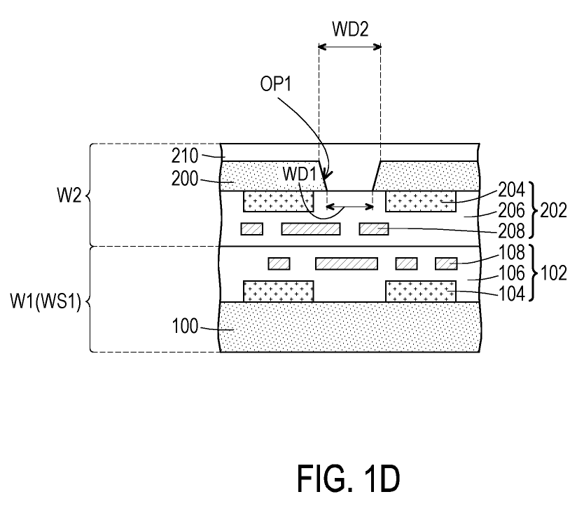

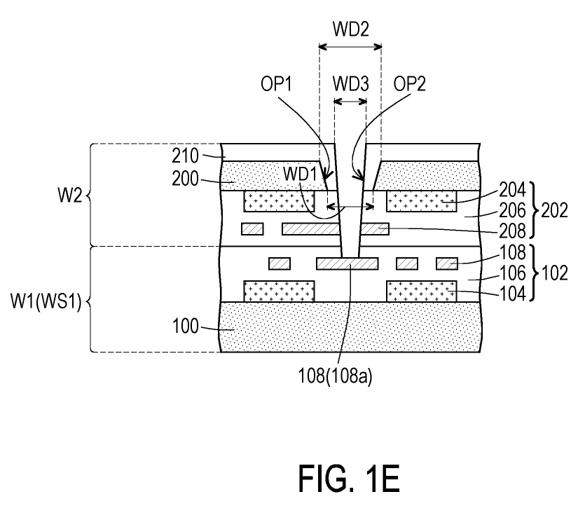

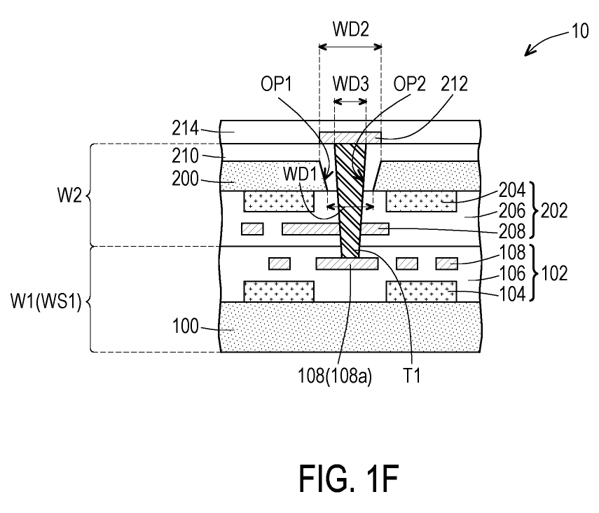

FIGS. 1A to1F are cross-sectional views of a manufacturing process of a semiconductor structure according to some embodiments of the invention.

Referring to FIG. 1A, a wafer structure WS1 is provided. The wafer structure WS1 may include a wafer W1. The wafer W1 may include a substrate 100 and a device layer 102 located on the substrate 100. In some embodiments, the substrate 100 may be a semiconductor substrate such as a silicon substrate. In some embodiments, the device layer 102 may include a semiconductor device 104, a dielectric structure 106, and a redistribution layer (RDL) 108. The semiconductor device 104 is located on the substrate 100. In some embodiments, the semiconductor device 104 is, for example, a logic device or a memory device. The dielectric structure 106 is located on the substrate 100. The semiconductor device 104 may be located in the dielectric structure 106. In some embodiments, the dielectric structure 106 may be a multilayer structure. In some embodiments, the material of the dielectric structure 106 is, for example, silicon oxide, silicon nitride, or a combination thereof. The RDL 108 is located in the dielectric structure 106. The RDL 108 may be a single-layer structure or a multilayer structure. The RDL 108 may be electrically connected to the semiconductor device 104. In some embodiments, the material of the RDL 108 is, for example, copper, tantalum, tantalum nitride, or a combination thereof.

Referring to FIG. 1B, a wafer W2 is bonded to the wafer structure WS1. The wafer W2 includes a substrate 200 and a device layer 202 located on the substrate 200. In some embodiments, the substrate 200 may be a semiconductor substrate such as a silicon substrate. In some embodiments, the device layer 202 may include a semiconductor device 204, a dielectric structure 206, and a RDL 208. The semiconductor device 204 is located on the substrate 200. In some embodiments, the semiconductor device 204 is, for example, a logic device or a memory device. The dielectric structure 206 is located on the substrate 200. The semiconductor device 204 may be located in the dielectric structure 206. In some embodiments, the dielectric structure 206 may be a multilayer structure. In some embodiments, the material of the dielectric structure 206 is, for example, silicon oxide, silicon nitride, or a combination thereof. The RDL 208 is located in the dielectric structure 206. The RDL 208 may be a single-layer structure or a multilayer structure. The RDL 208 may be electrically connected to the semiconductor device 204. In some embodiments, the material of the RDL 208 is, for example, copper, tantalum, tantalum nitride, or a combination thereof. In some embodiments, the method of bonding the wafer W2 to the wafer structure WS1 may be a fusion bonding method or a hybrid bonding method.

In some embodiments, a thinning process may be performed on the substrate 200. In some embodiments, the thinning process is, for example, a grinding process, a chemical mechanical polishing (CMP) process, or a combination thereof.

Referring to FIG. 1C, after the wafer W2 is bonded to the wafer structure WS1, an opening OP1 is formed in the substrate 200. The opening OP1 exposes the device layer 202. In some embodiments, a width WD1 of a portion of the opening OP1 closest to the device layer 202 may be smaller than a width WD2 of a portion of the opening OP1 farthest from the device layer 202. In the present embodiment, the substrate 100 does not have an opening aligned with the opening OP1. In some embodiments, the opening OP1 may be formed by patterning the substrate 200 by a lithography process and an etching process.

Referring to FIG. 1D, a dielectric layer 210 is formed on the substrate 200 and in the opening OP1. Therefore, the wafer W2 may further include the dielectric layer 210. In some embodiments, the material of the dielectric layer 210 is, for example, silicon oxide. In some embodiments, the method of forming the dielectric layer 210 is, for example, a chemical vapor deposition (CVD) method.

Referring to FIG. 1E, an opening OP2 may be formed in the dielectric layer 210 and the device layer 202. In some embodiments, the opening OP2 may pass through the device layer 202. The opening OP2 may extend into the wafer structure WS1. In some embodiments, the opening OP2 may be formed by patterning the dielectric layer 210, the device layer 202, and the wafer structure WS1 by a lithography process and an etching process. In the process of forming the opening OP2, the RDL 108a may be used as a blocking layer. That is, the wafer structure WS1 may include a blocking layer (e.g., RDL 108a).

Referring to FIG. 1F, a TSV T1 may be formed in the opening OP2. Therefore, a TSV T1 passing through the opening OP1 may be formed in the dielectric layer 210. The TSV T1 extends into the device layer 202. The TSV T1 may be in direct contact with the dielectric layer 210. In some embodiments, the TSV T1 may pass through the device layer 202. In some embodiments, the TSV T1 may further extend into the wafer structure WS1. In some embodiments, the bottom portion of the TSV T1 may be in direct contact with the blocking layer (e.g., RDL 108a). In some embodiments, the minimum width (e.g., width WD1) of the opening OP1 may be greater than the maximum width (e.g., width WD3) of the TSV T1. In some embodiments, the material of the TSV T1 is, for example, copper, tantalum, tantalum nitride, or a combination thereof. In some embodiments, the method of forming the TSV T1 may include the following steps. First, a TSV material layer (not shown) filling the opening OP2 may be formed on the dielectric layer 210. Then, the TSV material layer located outside the opening OP2 may be removed to form the TSV T1. In some embodiments, the method of removing the TSV material layer located outside the opening OP2 is, for example, a CMP method.

A RDL 212 and a dielectric layer 214 may be formed on the dielectric layer 210. The RDL 212 may be electrically connected to the TSV T1. In some embodiments, the material of the RDL 212 is, for example, copper, tantalum, tantalum nitride, or a combination thereof. The dielectric layer 214 is located on the dielectric layer 210. The RDL 212 is located in the dielectric layer 214. In some embodiments, the material of the dielectric layer 214 is, for example, silicon oxide, silicon nitride, or a combination thereof.

Based on the above embodiments, in the manufacturing method of the semiconductor structure 10, after the wafer W2 is bonded to the wafer structure WS1, the opening OP1 is formed in the substrate 200. The opening OP1 exposes the device layer 202. The dielectric layer 210 is formed on the substrate 200 and in the opening OP1. The TSV T1 passing through the opening OP1 is formed in the dielectric layer 210. Since the opening OP1, the dielectric layer 210, and the TSV T1 are formed after the wafer W2 is bonded to the wafer structure WS1, the processes of the opening OP1, the dielectric layer 210, and the TSV T1 can be prevented from causing the adverse effect on the semiconductor device (e.g., semiconductor device 204) in the device layer (e.g., device layer 202). In addition, since the processes of the opening OP1, the dielectric layer 210, and the TSV T1 are performed after the wafer W2 is bonded to the wafer structure WS1, the degree of freedom in design can be increased.

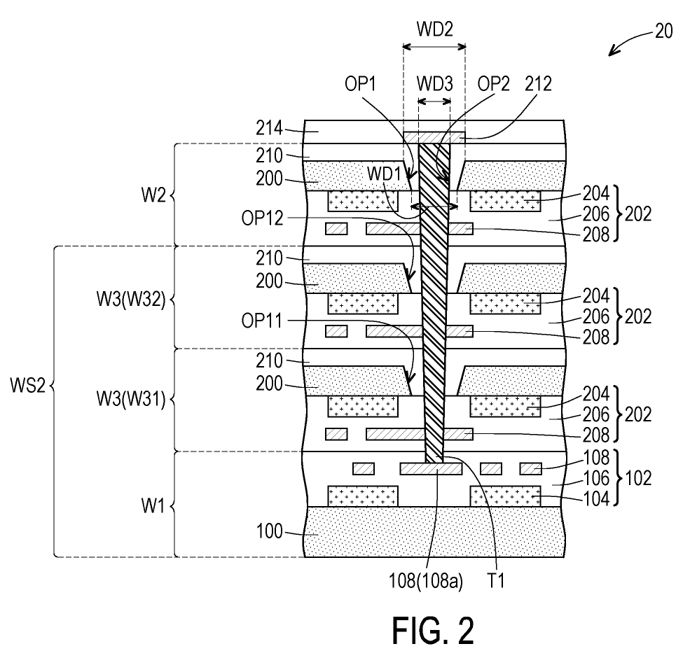

FIG. 2 is a cross-sectional view of a semiconductor structure according to other embodiments of the invention.

Referring to FIGS. 1F and 2, the difference between the semiconductor structure 20 of FIG. 2 and the semiconductor structure 10 of FIG. 1F is as follows. The wafer W2 of FIG. 1F is bonded to the wafer structure WS1, the wafer W2 of FIG. 2 is bonded to the wafer structure WS2, and the wafer structure WS1 and the wafer structure WS2 have different structures. In some embodiments, the method of bonding the wafer W2 to the wafer structure WS2 may be a fusion bonding method or a hybrid bonding method.

The difference between the wafer structure WS2 of FIG. 2 and the wafer structure WS1 of FIG. 1F is as follows. The wafer structure WS2 further includes at least one wafer W3. In the present embodiment, the number of the wafers W3 is, for example, plural, but the invention is not limited thereto. As long as the number of the wafers W3 is at least one, it falls within the scope of the invention. In the wafer W2 and the wafer W3, the same or similar components are denoted by the same or similar reference symbols, and the description thereof is omitted. In addition, the wafer W2 and the wafer W3 may have the same or different layout designs, and the wafers W3 may have the same or different layout designs.

In the wafer structure WS2, the wafer W31 may be bonded to the wafer W1, and the wafer W32 may be bonded to the wafer W31. In some embodiments, the method of bonding the wafer W31 to the wafer W1 may be a fusion bonding method or a hybrid bonding method. In some embodiments, the method of bonding the wafer W32 to the wafer W31 may be a fusion bonding method or a hybrid bonding method. In some embodiments, the substrate 200 of the wafer W31 may have an opening OP11 aligned with the opening OP1, and the substrate 200 of the wafer W32 may have an opening OP12 aligned with the opening OP1.

In addition, in the semiconductor structure 10 and the semiconductor structure 20, the same or similar components are denoted by the same reference symbols, and the description thereof is omitted.

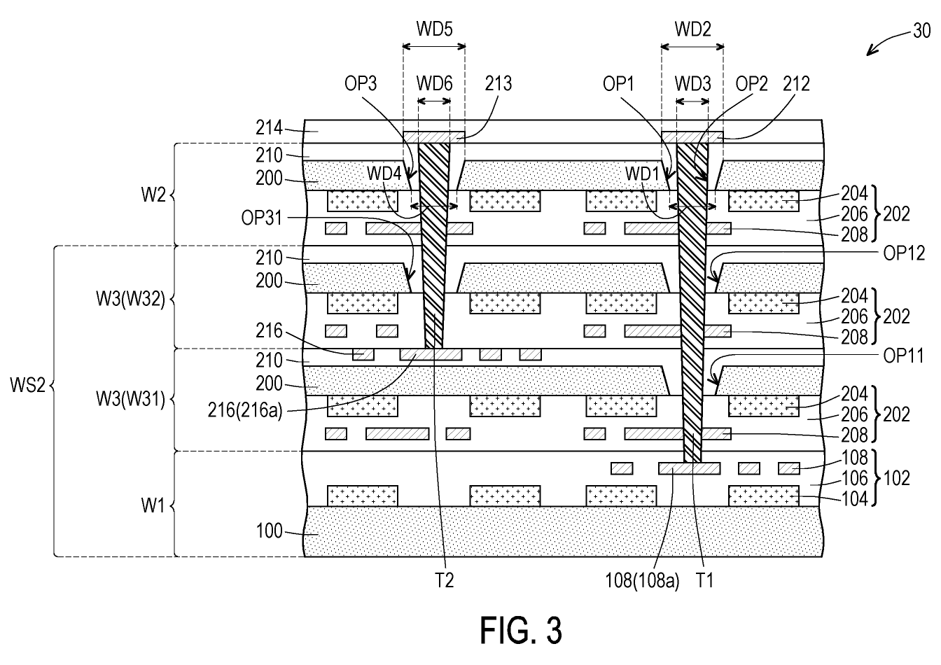

FIG. 3 is a cross-sectional view of a semiconductor structure according to other embodiments of the invention.

Referring to FIGS. 2 and 3, the difference between the semiconductor structure 30 of FIG. 3 and the semiconductor structure 20 of FIG. 2 is as follows. The manufacturing method of the semiconductor structure 30 may further include the following steps. An opening OP3 is formed in the substrate 200. The opening OP3 may expose the device layer 202. The dielectric layer 210 is formed in the opening OP3. A TSV T2 passing through the opening OP3 is formed in the dielectric layer 210. The TSV T2 extends into the device layer 202. The TSV T2 may be in direct contact with the dielectric layer 210. In some embodiments, the TSV T2 may pass through the device layer 202 of the wafer W2 and the device layer 202 of the wafer W3. In some embodiments, the TSV T1 and the TSV T2 may have different depths in the wafer structure WS2. For example, as shown in FIG. 3, the depth of the TSV T1 in the wafer structure WS2 may be greater than the depth of the TSV T2 in the wafer structure WS2. In the present embodiment, as shown in FIG. 3, the substrate 200 of the wafer W31 may have an opening OP11 aligned with the opening OP1, and the substrate 200 of the wafer W31 does not have an opening aligned with the opening OP3. In the present embodiment, as shown in FIG. 3, the substrate 200 of the wafer W32 may have an opening OP12 aligned with the opening OP1, and the substrate 200 of the wafer W32 may have an opening OP31 aligned with the opening OP3. In addition, a RDL 213 may be formed on the dielectric layer 210. The RDL 213 is located in the dielectric layer 214. The RDL 213 may be electrically connected to the TSV T2.

In some embodiments, a width WD4 of a portion of the opening OP3 closest to the device layer 202 may be smaller than a width WD5 of a portion of the opening OP3 farthest from the device layer 202. In some embodiments, the minimum width (e.g., width WD4) of the opening OP3 may be greater than the maximum width (e.g., width WD6) of the TSV T2.

In some embodiments, the wafer W31 may further include a RDL 216. The RDL 216 is located in the dielectric layer 210. The RDL 216 may be a single-layer structure or a multilayer structure. In some embodiments, the material of the RDL 216 is, for example, copper, tantalum, tantalum nitride, or a combination thereof. In some embodiments, the bottom portion of the TSV T2 may be in direct contact with a blocking layer (e.g., RDL 216a).

In addition, in the semiconductor structure 20 and the semiconductor structure 30, the same or similar components are denoted by the same reference symbols, and the description thereof is omitted.

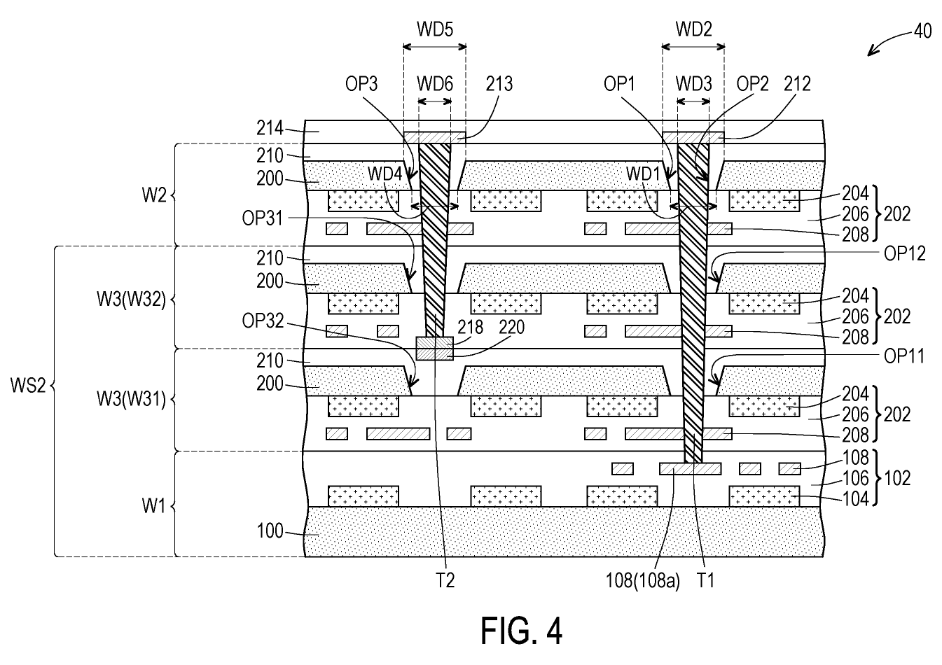

FIG. 4 is a cross-sectional view of a semiconductor structure according to other embodiments of the invention.

Referring to FIGS. 3 and 4, the difference between the semiconductor structure 40 of FIG. 4 and the semiconductor structure 30 of FIG. 3 is as follows. In the semiconductor structure 40, the substrate 200 of the wafer W31 may have an opening OP32 aligned with the opening OP3. In the semiconductor structure 40, the wafer structure WS2 may further include a blocking layer 218. The blocking layer 218 is located in the dielectric structure 206 of the wafer W32. The bottom portion of the TSV T2 may be in direct contact with the blocking layer 218. In the semiconductor structure 40, the wafer structure WS2 may further include a blocking layer 220. The blocking layer 220 is located in the dielectric layer 210 of the wafer W31. The blocking layer 220 may be in direct contact with the blocking layer 218. In some embodiments, the blocking layer 218 and the blocking layer 220 may be bonding pads or RDLs.

In addition, in the semiconductor structure 30 and the semiconductor structure 40, the same or similar components are denoted by the same reference symbols, and the description thereof is omitted.

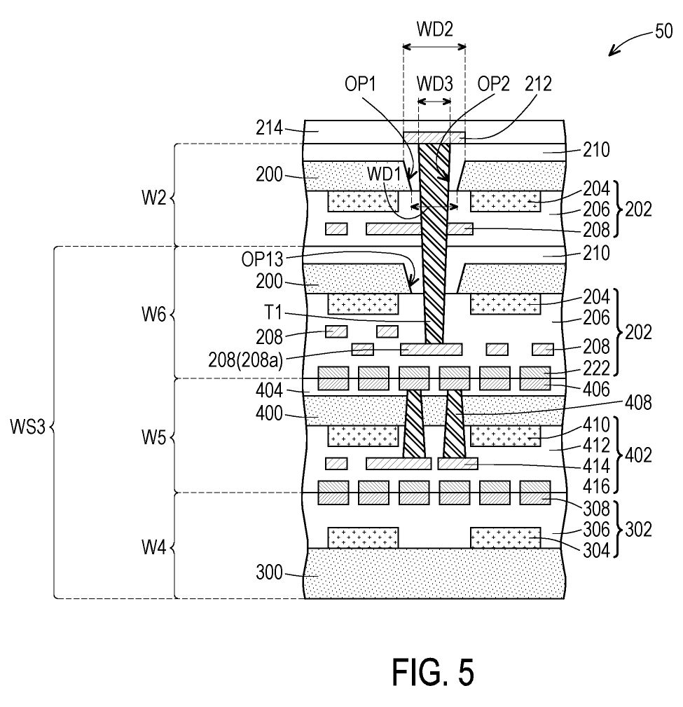

FIG. 5 is a cross-sectional view of a semiconductor structure according to other embodiments of the invention.

Referring to FIGS. 1F and 5, the difference between the semiconductor structure 50 of FIG. 5 and the semiconductor structure 10 of FIG. 1F is as follows. The wafer W2 of FIG. 1F is bonded to the wafer structure WS1, the wafer W2 of FIG. 5 is bonded to the wafer structure WS3, and the wafer structure WS1 and the wafer structure WS3 have different structures. In some embodiments, the method of bonding the wafer W2 to the wafer structure WS3 may be a fusion bonding method or a hybrid bonding method. In the present embodiment, as shown in FIG. 5, the bottom portion of the TSV T1 may be in direct contact with a blocking layer (e.g., RDL 208a).

The wafer structure WS3 may include a wafer W4, a wafer W5, and a wafer W6. The wafer W5 is bonded to the wafer W4. In some embodiments, the method of bonding the wafer W5 to the wafer W4 may be a hybrid bonding method. The wafer W6 is bonded to the wafer W5. In some embodiments, the method of bonding the wafer W6 to the wafer W5 may be a hybrid bonding method. The wafer W2 is bonded to the wafer W6. In some embodiments, the method of bonding the wafer W2 to the wafer W6 may be a fusion bonding method or a hybrid bonding method.

The wafer W4 may include a substrate 300 and a device layer 302. The device layer 302 may include a semiconductor device 304, a dielectric structure 306, and a bonding pad 308. The wafer W5 may include a substrate 400, a device layer 402, a dielectric layer 404, a bonding pad 406, and a TSV 408. The device layer 402 may include a semiconductor device 410, a dielectric structure 412, a RDL 414, and a bonding pad 416. The TSV 408 passes through the substrate 400 and are electrically connected to the bonding pad 406 and the RDL 414. The dielectric structure 412 may be bonded to the dielectric structure 306, and the bonding pad 416 may be bonded to the bonding pad 308. In the wafer W2 and the wafer W6, the same or similar components are denoted by the same or similar reference symbols, and the description thereof is omitted. In addition, the wafer W2 and the wafer W6 may have the same or different layout designs. The device layer 202 of the wafer W6 may further include a bonding pad 222. The dielectric structure 206 of the wafer W6 may be bonded to the dielectric layer 404, and the bonding pad 222 may be bonded to the bonding pad 406. The substrate 200 of the wafer W6 may have an opening OP13 aligned with the opening OP1, and the substrate 300 of the wafer W4 does not have an opening aligned with the opening OP1.

In addition, in the semiconductor structure 50 and the semiconductor structure 10, the same or similar components are denoted by the same reference symbols, and the description thereof is omitted.

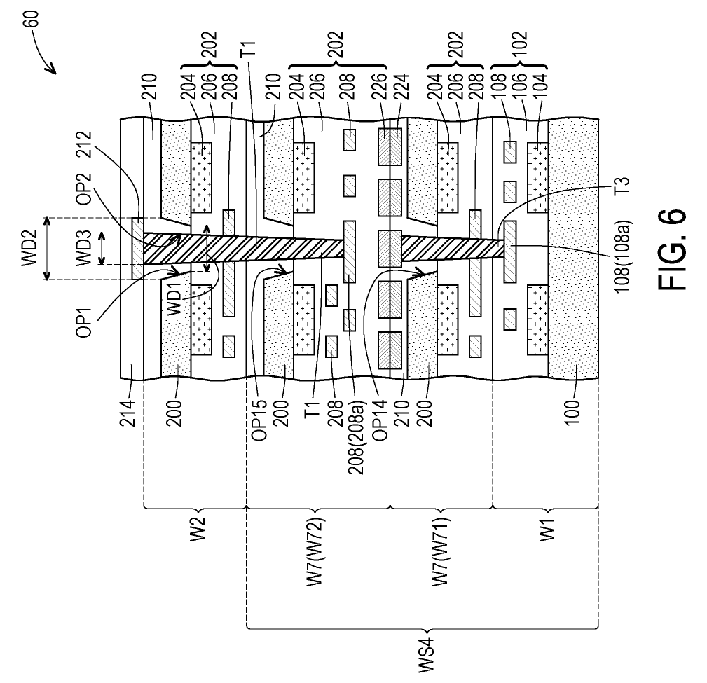

FIG. 6 is a cross-sectional view of a semiconductor structure according to other embodiments of the invention.

Referring to FIGS. 1F and 6, the difference between the semiconductor structure 60 of FIG. 6 and the semiconductor structure 10 of FIG. 1F is as follows. The wafer W2 of FIG. 1F is bonded to the wafer structure WS1, the wafer W2 of FIG. 6 is bonded to the wafer structure WS4, and the wafer structure WS1 and the wafer structure WS4 have different structures. In some embodiments, the method of bonding the wafer W2 to the wafer structure WS4 may be a fusion bonding method or a hybrid bonding method.

The wafer structure WS4 may include a wafer W1 and at least one wafer W7. The wafer W71 is bonded to the wafer W1. In some embodiments, the method of bonding the wafer W71 to the wafer W1 may be a fusion bonding method or a hybrid bonding method. The wafer W72 is bonded to the wafer W71. In some embodiments, the method of bonding the wafer W72 to the wafer W71 may be a hybrid bonding method. The wafer W2 is bonded to the wafer W72. In some embodiments, the method of bonding the wafer W2 to the wafer W72 may be a fusion bonding method or a hybrid bonding method.

In the wafer W2 and the wafer W7, the same or similar components are denoted by the same or similar reference symbols, and the description thereof is omitted. In addition, the wafer W2 and the wafer W7 may have the same or different layout designs. The wafer W71 may further include a bonding pad 224. The bonding pad 224 is located in the dielectric layer 210. The device layer 202 of the wafer W72 may further include a bonding pad 226. The bonding pad 226 is located in the dielectric structure 206. The dielectric structure 206 of the wafer W72 may be bonded to the dielectric layer 210 of the wafer W71, and the bonding pad 226 may be bonded to the bonding pad 224. The substrate 200 of the wafer W71 may have an opening OP14 aligned with the opening OP1, and the substrate 200 of the wafer W72 may have an opening OP15 aligned with the opening OP1.

In the present embodiment, as shown in FIG. 6, the bottom portion of the TSV T1 may directly contact a blocking layer (e.g., RDL 208a). In some embodiments, the wafer structure WS4 may further include a TSV T3. The TSV T3 is electrically connected to the bonding pad 224 and the RDL 108. In the present embodiment, as shown in FIG. 6, the bottom portion of the TSV T3 may be in direct contact with a blocking layer (e.g., RDL 108a).

In addition, in the semiconductor structure 60 and the semiconductor structure 10, the same or similar components are denoted by the same reference symbols, and the description thereof is omitted.

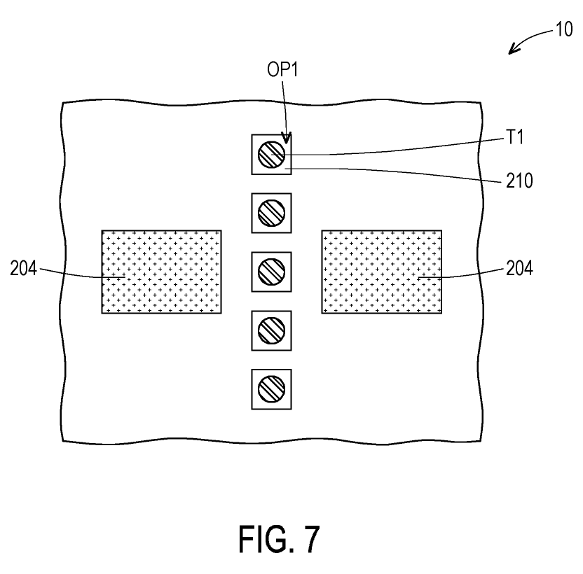

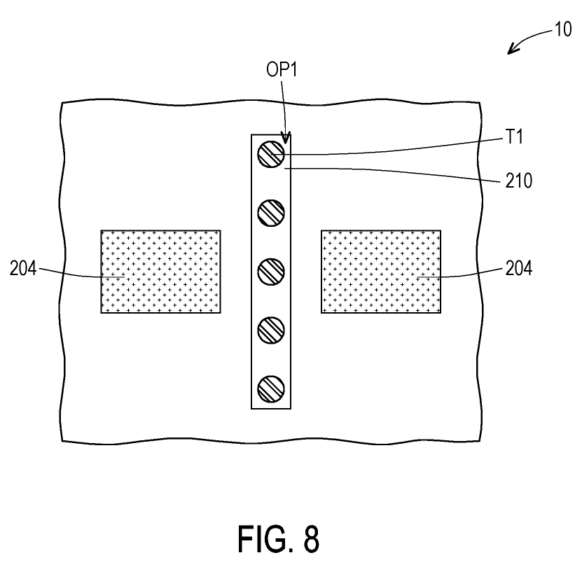

FIG. 7 is a top view of the semiconductor structure of FIG. 1F according to some embodiments of the invention. FIG. 8 is a top view of the semiconductor structure of FIG. 1F according to other embodiments of the invention. In FIGS. 7 and 8, some components in FIG. 1F are omitted to clearly illustrate the configuration relationship between the components in FIGS. 7 and 8.

Referring to FIG. 7 and FIG. 8, the semiconductor structure 10 may include TSVs T1. In some embodiments, as shown in FIG. 7, the substrate 200 may include openings OP1, and each of the TSVs T1 may be located in the corresponding opening OP1. In other embodiments, as shown in FIG. 8, the substrate 200 may include a single opening OP1, and the TSVs T1 may be located in the same opening OP1.

In addition, in FIGS. 1F, 7 and 8, the same or similar components are denoted by the same reference symbols, and the description thereof is omitted.

In summary, the semiconductor structure of the aforementioned embodiments includes the following steps. A wafer structure is provided. A first wafer is bonded to the wafer structure. The first wafer includes a first substrate and a first device layer located on the first substrate. After the first wafer is bonded to the wafer structure, a first opening is formed in the first substrate. The first opening exposes the first device layer. A dielectric layer is formed on the first substrate and in the first opening. A TSV passing through the first opening is formed in the dielectric layer. The first TSV extends into the first device layer. Since the first opening, the dielectric layer, and the first TSV are formed after the first wafer is bonded to the wafer structure, the processes of the first opening, the dielectric layer, and the first TSV can be prevented from causing the adverse effect on the semiconductor device in the first device layer. In addition, since the processes of the first opening, the dielectric layer, and the first TSV are performed after the first wafer is bonded to the wafer structure, the degree of freedom in design can be increased.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A manufacturing method of a semiconductor structure, comprising:
providing a wafer structure;
bonding a first wafer to the wafer structure, wherein the first wafer comprises a first substrate and a first device layer located on the first substrate;
after bonding the first wafer to the wafer structure, forming a first opening in the first substrate, wherein the first opening exposes the first device layer;
forming a dielectric layer on the first substrate and in the first opening; and
forming a first through-substrate via (TSV) passing through the first opening in the dielectric layer, wherein the first TSV extends into the first device layer.

2. The manufacturing method of the semiconductor structure according to claim 1, wherein a minimum width of the first opening is greater than a maximum width of the first TSV.

3. The manufacturing method of the semiconductor structure according to claim 1, wherein the first TSV is in direct contact with the dielectric layer.

4. The manufacturing method of the semiconductor structure according to claim 1, wherein the first TSV passes through the first device layer.

5. The manufacturing method of the semiconductor structure according to claim 1, wherein the first TSV further extends into the wafer structure.

6. The manufacturing method of the semiconductor structure according to claim 1, wherein a width of a portion of the first opening closest to the first device layer is smaller than a width of a portion of the first opening farthest from the first device layer.

7. The manufacturing method of the semiconductor structure according to claim 1, wherein a method of forming the first TSV comprises:
forming a second opening in the dielectric layer and the first device layer; and
forming the first TSV in the second opening.

8. The manufacturing method of the semiconductor structure according to claim 1, wherein a method of bonding the first wafer to the wafer structure comprises a fusion bonding method.

9. The manufacturing method of the semiconductor structure according to claim 1, wherein a method of bonding the first wafer to the wafer structure comprises a hybrid bonding method.

10. The manufacturing method of the semiconductor structure according to claim 1, further comprising:
before forming the first opening, performing a thinning process on the first substrate.

11. The manufacturing method of the semiconductor structure according to claim 1, wherein the wafer structure comprises a second wafer, and the second wafer comprises a second substrate and a second device layer located on the second substrate.

12. The manufacturing method of the semiconductor structure according to claim 11, wherein the second substrate does not have an opening aligned with the first opening.

13. The manufacturing method of the semiconductor structure according to claim 11, wherein the second substrate has a second opening aligned with the first opening.

14. The manufacturing method of the semiconductor structure according to claim 1, wherein
the wafer structure comprises a blocking layer, and
a bottom portion of the first TSV is in direct contact with the blocking layer.

15. The manufacturing method of the semiconductor structure according to claim 1, further comprising:
forming a second opening in the first substrate, wherein the second opening exposes the first device layer;
forming the dielectric layer in the second opening; and
forming a second TSV passing through the second opening in the dielectric layer, wherein the second TSV extends into the first device layer.

16. The manufacturing method of the semiconductor structure according to claim 15, wherein the second TSV is in direct contact with the dielectric layer.

17. The manufacturing method of the semiconductor structure according to claim 15, wherein the first TSV and the second TSV have different depths in the wafer structure.

18. The manufacturing method of the semiconductor structure according to claim 15, wherein the wafer structure comprises a second wafer, and the second wafer comprises a second substrate and a second device layer located on the second substrate.

19. The manufacturing method of the semiconductor structure according to claim 18, wherein
the second substrate has a third opening aligned with the first opening, and
the second substrate does not have an opening aligned with the second opening.

20. The manufacturing method of the semiconductor structure according to claim 18, wherein
the second substrate has a third opening aligned with the first opening, and
the second substrate has a fourth opening aligned with the second opening.
